(19) United States
(12) Patent Application Publication
(10) Pub. No.: US 2017/0301875 A1
(43) Pub. Date: Oct. 19, 2017

(54) ORGANIC LIGHT-EMITTING DISPLAY PANEL AND DEVICE

(71) Applicants: SHANGHAI TIANMA AM-OLED CO., LTD., SHANGHAI (CN); TIANMA MICRO-ELECTRONICS CO.,LTD., Shenzhen (CN)

(72) Inventors: Xiangcheng Wang, Shanghai (CN); Yuji Hamada, Shanghai (CN); Jinghua Niu, Shanghai (CN); Wei He, Shanghai (CN); Shuang Cheng, Shanghai (CN)

(73) Assignees: SHANGHAI TIANMA AM-OLED CO., LTD., SHANGHAI (CN); TIANMA MICRO-ELECTRONICS CO.,LTD., Shenzhen (CN)

(21) Appl. No.: 15/638,311

(22) Filed: Jun. 29, 2017

(30) Foreign Application Priority Data
Dec. 30, 2016 (CN) 201611255356.5

(51) Int. Cl. H01L 51/50; H01L 51/52

(52) U.S. Cl. CPC H01L 51/5024; H01L 51/508; H01L 51/5056; H01L 51/5203

(57) ABSTRACT

An organic light-emitting display panel and an organic light-emitting display device are disclosed. The organic light-emitting display panel includes: a first electrode and a second electrode that are stacked; at least two light-emitting layers are provided between the first electrode and the second electrode, and a first auxiliary functional layer and a second auxiliary functional layer are provided between adjacent two light-emitting layers; the first auxiliary functional layer is close to the first electrode, the second auxiliary functional layer is close to the second electrode, the first auxiliary functional layer includes an electron transport-type host material, and the second auxiliary functional layer includes a hole transport-type host material;

the first auxiliary functional layer includes an N-type dopant material; the second auxiliary functional layer includes a P-type dopant material.

### CROSS-REFERENCE TO RELATED APPLICATIONS

This application claims priority to Chinese Patent Application No. 201611255356.5, filed on Dec. 30, 2016 and entitled “ORGANIC LIGHT-EMITTING DISPLAY PANEL AND DEVICE”, the disclosure of which is incorporated herein by reference in its entirety.

### TECHNICAL FIELD

Embodiments of the present invention relate to organic light-emitting display technologies, and in particular, to an organic light-emitting display panel and an organic light-emitting display device.

### BACKGROUND

Due to the technical advantages of no backlight source, high contrast, small thickness, large visual angle and fast reaction speed, etc., Organic Light-Emitting Display has become one of the important development directions of the display industries.

In the existing organic light-emitting display panel with double light-emitting layers, the materials forming the light-emitting layers will be decomposed and deteriorated with the increase of working time, although carrier balance may be well adjusted and controlled. After decomposition and deterioration, the light-emitting layer may capture the holes and electrons that are being transported, and hence the recombination region of electrons and holes in the organic light-emitting display panel may be moved, which causes the color coordinate of the organic light-emitting display panel unstable, thereby decreasing the light-emitting efficiency of the organic light-emitting display panel.

### SUMMARY

The present invention provides an organic light-emitting display panel and an organic light-emitting display device, thereby improving the stability of the color coordinate of the organic light-emitting display panel and hence improving the light-emitting efficiency of the organic light-emitting display panel.

In a first aspect of the embodiments of the present invention, there provides an organic light-emitting display panel, which includes a first electrode and a second electrode that are stacked;

at least two light-emitting layers are provided between the first electrode and the second electrode, and a first auxiliary functional layer and a second auxiliary functional layer are provided between adjacent two of the at least two light-emitting layers;

the first auxiliary functional layer is close to the first electrode, the second auxiliary functional layer is close to the second electrode, the first auxiliary functional layer includes an electron transport-type host material, and the second auxiliary functional layer includes a hole transport-type host material;

the first auxiliary functional layer includes an N-type dopant material; and/or, the second auxiliary functional layer includes a P-type dopant material.

In another aspect of the embodiments of the present invention, there further provides an organic light-emitting display device, which includes any of the organic light-emitting display panels according to the embodiments of the present invention.

In the embodiments of the present invention, by setting a first auxiliary functional layer and a second auxiliary functional layer between adjacent two of the light-emitting layers, it solves the problems of the existing organic light-emitting display panels that, due to the decomposition and deterioration of the materials of the light-emitting layer, the recombination region of electrons and holes in the organic light-emitting display panel will be moved which causes the color coordinate of the organic light-emitting display panel unstable and decreases the light-emitting efficiency of the organic light-emitting display panel. Thus, the organic light-emitting display panel according to the embodiments of the present invention can improve the stability of the color coordinate of the organic light-emitting display panel and the light-emitting efficiency of the organic light-emitting display panel.

### BRIEF DESCRIPTION OF THE DRAWINGS

FIG. 1 is a structural representation of an existing organic light-emitting display panel;

FIG. 2 is a structural representation of an organic light-emitting display panel according to one embodiment of the present invention;

FIG. 3 is a structural representation of another organic light-emitting display panel according to one embodiment of the present invention; and

FIG. 4 is a structural representation of an organic light-emitting display device according to one embodiment of the present invention.

### DETAILED DESCRIPTION

The present invention will be further illustrated in detail in conjunction with the drawings and embodiments. It may be understood that, the specific embodiments described herein are only for explaining, rather than to limit, the present invention. Additionally, it further needs to be noted that, for convenient description, the drawings only show the parts related to the disclosure, rather than the whole structure.

FIG. 1 is a structural representation of an existing organic light-emitting display panel. Referring to FIG. 1, the organic light-emitting display panel includes an anode 11, a hole transport layer 12, a first light-emitting layer 13, a second light-emitting layer 14, an electron transport layer 15 and a cathode 16, which are stacked in turn.

The working principle of the organic light-emitting display panel lies in that: during operation, a bias voltage is applied between the anode 11 and the cathode 16 of the organic light-emitting display panel, so that holes and electrons can break through the interfacial energy barrier and migrate respectively from the hole transport layer and the electron transport layer 15 to the light-emitting layer (including the first light-emitting layer 13 and the second light-emitting layer 14), and on the light-emitting layer (including the first light-emitting layer 13 and the second light-emitting layer 14), electrons and holes are recombined to generate excitons. The excitons are unstable, and energy can be released. The energy is transferred to the molecules of the light-emitting material in the light-emitting layer (including the first light-emitting layer 13 and the second light-emitting layer 14), so that the molecules transit from a ground state to an excited state. The excited state is very unstable, and thus the excited molecules return to the ground state from the excited state, so that a light emitting phenomenon appears due to radiative transition.

As described in the background, with the increase of working time, irreversible chemical changes, such as decomposition, tends to occur to the materials of the first light-emitting layer 13 and the second light-emitting layer 14, which causes the materials of the first light-emitting layer 13 and the second light-emitting layer 14 to be deteriorated. Exemplarily, referring to FIG. 1, if the material of the first light-emitting layer 13 is deteriorated, the deteriorated first light-emitting layer 13 will capture the holes transported from the anode 11, so that the recombination region of electrons and holes in the organic light-emitting display panel will migrate towards the side of the anode 11. If the recombination region migrates to the hole transport layer 12, because no light-emitting material is doped in the hole transport layer 12, the energy cannot be transported to the light-emitting material thereof during the exciton attenuation process generated by hole and electron recombination, so that the organic light-emitting display panel cannot emit light normally, and the color coordinate of the organic light-emitting display panel is unstable, hence causing a low light-emitting efficiency of the organic electroluminescent device.

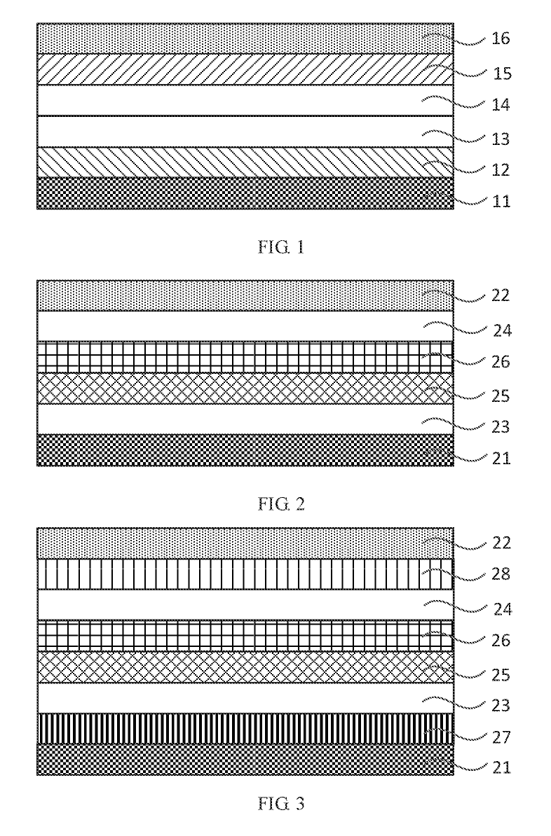

FIG. 2 is a structural representation of an organic light-emitting display panel according to one embodiment of the present invention. Referring to FIG. 2, the organic light-emitting display panel includes: a first electrode 21 and a second electrode 22 that are stacked; at least two light-emitting layers provided between the first electrode 21 and the second electrode 22 (Illustratively in FIG. 2, only two light-emitting layers, i.e., a first light-emitting layer 23 and a second light-emitting layer 24 respectively, are included). A first auxiliary functional layer 25 and a second auxiliary functional layer 26 are provided between adjacent two light-emitting layers; the first auxiliary functional layer 25 is close to the first electrode 21, the second auxiliary functional layer 26 is close to the second electrode 22, the first auxiliary functional layer 25 includes an electron transport-type host material, and the second auxiliary functional layer 26 includes a hole transport-type host material; the first auxiliary functional layer 25 includes an N-type dopant material; and/or, the second auxiliary functional layer 26 includes a P-type dopant material. Wherein, the first electrode 21 is an anode, and the second electrode 22 is a cathode.

During operation, if the material of the first light-emitting layer 23 is deteriorated, the deteriorated first light-emitting layer 23 would capture the holes transported from the first electrode 21, so that the holes injected by the first electrode 21 cannot pass though the first light-emitting layer 23 to reach the second light-emitting layer 24. However, since holes may be generated on the interface between the first auxiliary functional layer 25 and the second auxiliary functional layer 26, the holes can migrate towards the second light-emitting layer 24 via the second auxiliary functional layer 26 after being generated on the interface between the first auxiliary functional layer 25 and the second auxiliary functional layer 26. In the second light-emitting layer 24, the holes generated on the interface between the first auxiliary functional layer 25 and the second auxiliary functional layer 26 may be recombined with the electrons injected by the second electrode 22 in order to generate excitons, hence making the organic light-emitting display panel emit light.

During operation, if the material of the second light-emitting layer 24 is deteriorated, the deteriorated second light-emitting layer 24 would capture the electrons transported from the second electrode 22, so that the electrons injected by the second electrode 22 cannot pass through the second light-emitting layer 24 to reach the first light-emitting layer 23. However, since electrons may be generated on the interface between the first auxiliary functional layer 25 and the second auxiliary functional layer 26, the electrons can migrate towards the first light-emitting layer 23 via the first auxiliary functional layer 25 after being generated on the interface between the first auxiliary functional layer 25 and the second auxiliary functional layer 26. In the first light-emitting layer 23, the electrons generated on the interface between the first auxiliary functional layer 25 and the second auxiliary functional layer 26 may be recombined with the holes injected by the first electrode 21 in order to generate excitons, hence making the organic light-emitting display panel emit light.

In the embodiments of the present invention, by providing a first auxiliary functional layer 25 and a second auxiliary functional layer 26 between adjacent two light-emitting layers, it solves the problems of the existing organic light-emitting display panels that, due to the decomposition and deterioration of the materials of the light-emitting layer, the recombination region of electrons and holes in the organic light-emitting display panel will be moved which causes the color coordinate of the organic light-emitting display panel unstable and decreases the light-emitting efficiency of the organic light-emitting display panel. Thus, the organic light-emitting display panel according to the embodiments of the present invention can improve the stability of the color coordinate of the organic light-emitting display panel and the light-emitting efficiency of the organic light-emitting display panel.

In the above technical solutions, the N-type dopant material refers to a material with a high electron mobility. Exemplarily, the N-type dopant material includes at least one of an alkali metal, an alkaline earth metal and a rare-earth metal. Typically, the N-type dopant material includes ytterbium. With such an arrangement, the migration efficiency of electrons in the first auxiliary functional layer 25 may be improved. During specific design, the appropriate mass percent of the N-type dopant material in the first auxiliary functional layer 25 and the appropriate thickness of the first auxiliary functional layer 25 may be selected according to the performance requirement of the organic light-emitting display panel to be manufactured. Optionally, the mass percent of the N-type dopant material in the first auxiliary functional layer 25 may be greater than or equal to 5% and less than or equal to 50%. The thickness of the first auxiliary functional layer 25 may be greater than or equal to 10 nm and less than or equal to 60 nm.

Similarly, the P-type dopant material refers to a material with a high hole mobility. Exemplarily, the P-type dopant material includes at least one of 2,3,6,7,10,11-hexacyano-1,4,5,8,9,12-hexaazatriphenylene(HAT-CN), 2,3,5,6-tetrafluoro-7,7′,8,8′-tetracyanoquinodimethane (F4-TCNQ), NOVALED NDP-9 (a material with a product model of NDP-9 sold by NOVALED Company) or molybdenum oxide. With such an arrangement, the migration efficiency of holes in the second auxiliary functional layer 26 may be improved. During specific design, the appropriate P-type dopant material in the second auxiliary functional layer 26 and the appropriate thickness of the second auxiliary functional layer 26 may be selected according to the performance requirement of the organic light-emitting display panel to be manufactured. Optionally, the mass percent of the P-type dopant material in the second auxiliary functional layer 26 may be greater than or equal to 1% and less than or equal to 10%. The thickness of the second auxiliary functional layer 26 may be greater than or equal to 20 nm and less than or equal to 100 nm.

It should be noted that, in specific design, in order to adjust the charge balance in the organic light-emitting display panel, the mass percent of the N-type dopant material in the first auxiliary functional layer 25, the thickness of the first auxiliary functional layer 25, the P-type dopant material in the second auxiliary functional layer 26 and the thickness of the second auxiliary functional layer 26 need to be considered comprehensively, rather than being treated independently.

Based on the above technical solutions, the light-emitting layer (including the first light-emitting layer 23 and/or the second light-emitting layer 24) may include at least one host material and at least one guest dopant. Exemplarily, the light-emitting layer only includes one host material and one guest dopant, or the light-emitting layer includes two host materials and one guest dopant, and so on. The host material in the light-emitting layer may include at least one of CPB (with a structural formula of

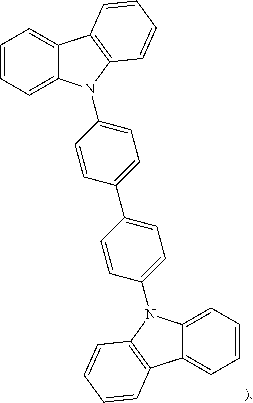 [SMILES: c1ccc2c(c1)c1ccccc1n2-c1ccc(-c2ccc(-n3c4ccccc4c4ccccc43)cc2)cc1]

TCTA (with a structural formula of

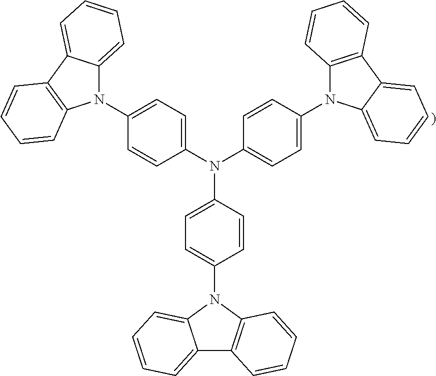 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

and AND (with a structural formula of

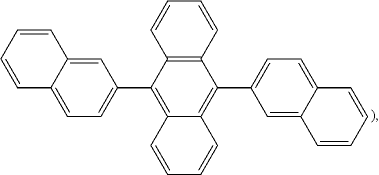 [SMILES: c1ccc2cc(-c3c4ccccc4c(-c4ccc5ccccc5c4)c4ccccc34)ccc2c1]

The guest dopant in the light-emitting layer (including the first light-emitting layer 23 and/or the second light-emitting layer 24) is a phosphorescent material or a fluorescent material. It should be noted that, the light-emitting efficiency of a light-emitting layer including a phosphorescent material is high, but the lifetime thereof is relatively short. On the other hand, the light-emitting efficiency of a light-emitting layer including a fluorescent material is low, but the lifetime thereof is relatively long. During practical manufacturing, optionally, it is possible that the first light-emitting layer 23 and/or the second light-emitting layer 24 only include(s) a phosphorescent material, the first light-emitting layer 23 and/or the second light-emitting layer 24 only include(s) a fluorescent material, or the first light-emitting layer 23 and/or the second light-emitting layer 24 include(s) both a phosphorescent material and a fluorescent material.

If the guest dopant in the light-emitting layer is a phosphorescent material, the phosphorescent material may include at least one of tri(2-phenylpyridinato)iridium(III) (IRPPY3), bis(4,6-difluorophenylpyridinato-N,C2)picolinatoiridium (Firpic) or bis(2-(2′-benzothienyl)pyridinato-N,C3′)(acetylacetonate)iridium (BTP(IR)acac). The thickness of the light-emitting layer may be greater than or equal to 20 nm and less than or equal to 40 nm.

If the guest dopant in the light-emitting layer is a fluorescent material, the fluorescent material may include at least one of BD1 (with a structural formula of

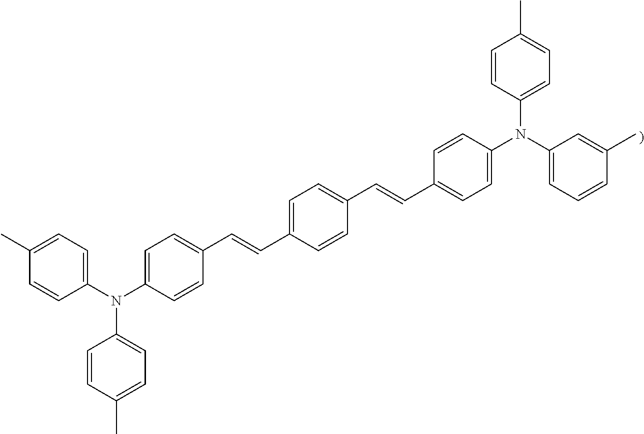

or GD1 (with a structural formula of

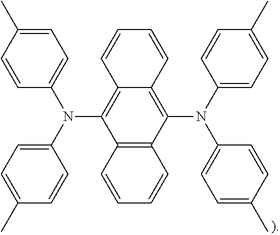 [SMILES: Cc1ccc(N(c2ccc(C)cc2)c2c3ccccc3c(N(c3ccc(C)cc3)c3ccc(C)cc3)c3ccccc23)cc1]

The thickness of the light-emitting layer may be greater than or equal to 15 nm and less than or equal to 40 nm.

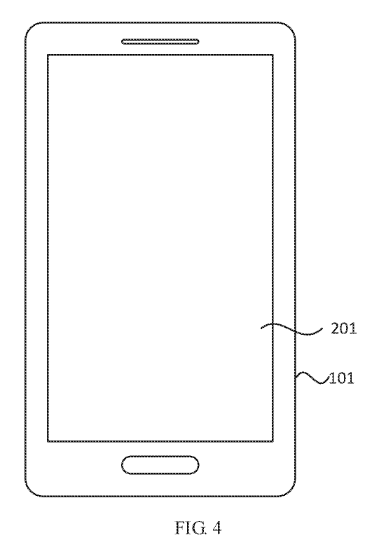

FIG. 3 is a structural representation of another organic light-emitting display panel according to one embodiment of the present invention. In comparison with FIG. 2, the organic light-emitting display panel in FIG. 3 further includes a third auxiliary functional layer 27 and a fourth auxiliary functional layer 28.

The third auxiliary functional layer 27 is located between the first electrode 21 and the light-emitting layer (that is, the first light-emitting layer 23) closest to the first electrode 21, and the third auxiliary functional layer 27 includes at least one of a hole injection layer, a hole transport layer and an electron blocking layer. The fourth auxiliary functional layer 28 is located between the second electrode 22 and the light-emitting layer (that is, the second light-emitting layer 24) closest to the second electrode 22, and the fourth auxiliary functional layer 28 includes at least one of an electrode injection layer, an electron transport layer and a hole blocking layer.

By providing the third auxiliary functional layer 27, on one hand, holes can be injected from the first electrode 21 into the first light-emitting layer 23 more easily, and on the other hand, the electrons injected from the second electrode 22 into the second light-emitting layer 24 can be blocked from passing through the first light-emitting layer 23 to migrate towards the first electrode 21, so that the holes and electrons can be recombined in the light-emitting layer, and hence the light-emitting efficiency of the organic light-emitting display panel can be further improved. Similarly, by providing the fourth auxiliary functional layer 28, on one hand, electrons can be injected from the second electrode 22 into the second light-emitting layer 24 more easily, and on the other hand, the holes injected from the first electrode 21 into the first light-emitting layer 23 can be blocked from passing through the second light-emitting layer 24 to migrate towards the second electrode 22, so that the holes and electrons can be recombined in the light-emitting layer, and hence the light-emitting efficiency of the organic light-emitting display panel can be further improved.

It should be noted that, the organic light-emitting display panel in FIG. 3 includes both a third auxiliary functional layer 27 and a fourth auxiliary functional layer 28, which is just one specific example of the present invention, rather than limiting the present invention. During specific design, the organic light-emitting display panel may only include the third auxiliary functional layer 27, or alteratively it may only include the fourth auxiliary functional layer 28.

Based on the above technical solutions, the light emitted by the organic light-emitting display panel may include red light, green light, blue light or white light.

TABLE 1

| | External quantum efficiency | Lifetime |
|---|---|---|
| Embodiment 1 | 280% | 80% |
| Embodiment 1 | 300% | 30% |
| Embodiment 2 | 100% | 100% |

Table 1 shows performance parameters of different organic light-emitting display panels that emit green light. In Table 1, Embodiment 1 and Embodiment 2 are existing organic light-emitting display panels, and the organic light-emitting display panel in Embodiment 1 has a structure of: first electrode/hole transport layer/light-emitting layer (CPB:IRPPY3)/electron transport layer/second electrode, representing that the organic light-emitting display panel in Embodiment 1 includes a first electrode, a hole transport layer, a light-emitting layer, an electron transport layer and a second electrode which are stacked in turn, where the host material of the light-emitting layer is CPB, and the guest dopant is IRPPY3. Similarly, the organic light-emitting display panel in Embodiment 2 has a structure of: first electrode/hole transport layer/light-emitting layer (ADN:GD1)/electron transport layer/second electrode. The organic light-emitting display panel in Embodiment 1 has a structure of: first electrode/hole transport layer/first light-emitting layer (CPB:IRPPY3)/first auxiliary functional layer (doped with ytterbium)/second auxiliary functional layer (doped with NOVALED NDP-9)/first light-emitting layer (ADN:GD1)/electron transport layer/second electrode. In Table 1, each performance parameter for characterizing the performance of the organic light-emitting display panel is obtained by taking the data measured in Embodiment 2 as a reference after being measured under the same experimental conditions (including the same current density). Exemplarily, in Embodiment 1, the external quantum efficiency of the organic light-emitting display panel is 300%, representing that the external quantum efficiency of the organic light-emitting display panel in Embodiment 1 is 300% (i.e., 3 times) of the external quantum efficiency of the organic light-emitting display panel in Embodiment 2.

Referring to Table 1, in comparison with the lifetime of the organic light-emitting display panel in Embodiment 1, the lifetime of the organic light-emitting display panel in Embodiment 1 is somewhat lowered, but the external quantum efficiency of the organic light-emitting display panel in Embodiment 1 is 2.8 times of the external quantum efficiency of the organic light-emitting display panel in Embodiment 1. In comparison with the external quantum efficiency of the organic light-emitting display panel in Embodiment 2, the external quantum efficiency of the organic light-emitting display panel in Embodiment 1 is somewhat lowered, but the lifetime of the organic light-emitting display panel in Embodiment 1 is much longer than the lifetime of the organic light-emitting display panel in Embodiment 1. The above data indicate that, the organic light-emitting display panel according to the present application positively facilitates improving the performance of the organic light-emitting display panel.

Table 2 shows the performance parameters of different organic light-emitting display panels that emit blue light. In Table 2, Embodiment 1 and Embodiment 2 are existing organic light-emitting display panels, and the organic light-emitting display panel in Embodiment 1 has a structure of: first electrode/hole transport layer/light-emitting layer (TCTA:Firpic)/electron transport layer/second electrode, and the organic light-emitting display panel in Embodiment 2 has a structure of: first electrode/hole transport layer/light-emitting layer (ADN:BD1)/electron transport layer/second electrode. The organic light-emitting display panel in Embodiment 1 has a structure of: first electrode/hole transport layer/first light-emitting layer (TCTA:Firpic)/first auxiliary functional layer (doped with ytterbium)/second auxiliary functional layer (doped with NOVALED NDP-9)/second light-emitting layer (ADN:BD1)/electron transport layer/second electrode. In Table 2, each performance parameter for characterizing the performance of the organic light-emitting display panel is obtained by taking the data measured in Embodiment 2 as a reference after being measured under the same experimental conditions (including the same current density).

TABLE 2

| | External quantum efficiency | Lifetime |
|---|---|---|
| Embodiment 1 | 250% | 50% |
| Embodiment 1 | 280% | 5% |
| Embodiment 2 | 100% | 100% |

Referring to Table 2, in comparison with the lifetime of the organic light-emitting display panel in Embodiment 1, the lifetime of the organic light-emitting display panel in Embodiment 1 is somewhat lowered, but the external quantum efficiency of the organic light-emitting display panel in Embodiment 1 is 2.5 times of the external quantum efficiency of the organic light-emitting display panel in Embodiment 1. In comparison with the external quantum efficiency of the organic light-emitting display panel in Embodiment 2, the external quantum efficiency of the organic light-emitting display panel in Embodiment 1 is somewhat lowered, but the lifetime of the organic light-emitting display panel in Embodiment 1 is much longer than the lifetime of the organic light-emitting display panel in Embodiment 1. The above data indicate that, the organic light-emitting display panel according to the present application positively facilitates improving the performance of the organic light-emitting display panel.

Table 3 shows the performance parameters of different organic light-emitting display panels that emit white light. In Table 3, the organic light-emitting display panel in Embodiment 1 has a structure of: first electrode/hole transport layer/first light-emitting layer (BCP:BTP(IP)acac)/first auxiliary functional layer (without being doped with any N-type material)/lithium fluoride/molybdenum oxide/second auxiliary functional layer (without being doped with any P-type material)/second light-emitting layer (ADN:BD1)/electron transport layer/second electrode. The organic light-emitting display panel in Embodiment 1 has a structure of: first electrode/hole transport layer/first light-emitting layer (BCP:BTP(IP)acac)/first auxiliary functional layer (doped with ytterbium)/second auxiliary functional layer (doped with NOVALED NDP-9)/second light-emitting layer (ADN:BD1)/electron transport layer/second electrode. In Table 3, each performance parameter for characterizing the performance of the organic light-emitting display panel is obtained by taking the data measured in Contrast Embodiment 1 as a reference after being measured under the same experimental conditions (including the same current density).

TABLE 3

| | Bias Voltage | External quantum efficiency | Lifetime |
|---|---|---|---|
| Embodiment 1 | 95% | 110% | 120% |
| Embodiment 1 | 100% | 100% | 100% |

Referring to Table 3, In comparison with the organic light-emitting display panel in Embodiment 1, the bias voltage required for the organic light-emitting display panel in Embodiment 1 is lower, the external quantum efficiency thereof is higher, and the lifetime thereof is longer. This indicates that, the organic light-emitting display panel according to the present application positively facilitates lowering the working voltage of the organic light-emitting display panel, improving the light-emitting efficiency of the organic light-emitting display panel and prolonging the lifetime of the organic light-emitting display panel.

It should be noted that, in the manufacturing process of each of the organic light-emitting panels according to the present application, the first electrode may be first formed on a substrate, and then each film layer located between the first electrode and the second electrode is formed in turn, and finally the second electrode is formed; or alternatively, the second electrode may be first formed on the substrate, and then each film layer located between the first electrode and the second electrode is formed in turn, and finally the first electrode is formed. That is, the organic light-emitting display panel may have an upright structure, or it may have an inverted structure.

Additionally, in each organic light-emitting panel according to the present disclosure, the first electrode may be used as a light exit side electrode, or the second electrode may be used as a light exit side electrode, or the first electrode and the second electrode may be both used as light exit side electrodes.

One embodiment of the present invention further provides an organic light-emitting display device. FIG. 4 is a structural representation of an organic light-emitting display device according to one embodiment of the present invention. Referring to FIG. 4, the organic light-emitting display device 101 includes any organic light-emitting display panel 201 according to the embodiments of the present invention. Specifically, the organic light-emitting display device may be a mobile phone, a notebook computer, an intelligent wearable device and an information inquiry machine in a public hall.

In the organic light-emitting device according to the embodiments of the present invention, by providing a first auxiliary functional layer and a second auxiliary functional layer between adjacent two light-emitting layers of organic light-emitting display panel thereof, it solves the problems of the existing organic light-emitting display panels that, due to the decomposition and deterioration of the materials of the light-emitting layer, the recombination region of electrons and holes in the organic light-emitting display panel will be moved which causes the color coordinate of the organic light-emitting display panel unstable and decreases the light-emitting efficiency of the organic light-emitting display panel. Thus, the organic light-emitting display panel according to the embodiments of the present invention can improve the stability of the color coordinate of the organic light-emitting display panel and the light-emitting efficiency of the organic light-emitting display panel.

It should be noted that the embodiments of the present invention and the technical principles used therein are described as above. It should be appreciated that the invention is not limited to the particular embodiments described herein, and any apparent alterations, modification and substitutions can be made without departing from the scope of protection of the invention. Accordingly, while the invention is described in detail through the above embodiments, the invention is not limited to the above embodiments and can further include other additional embodiments without departing from the concept of the invention.

What is claimed is:

1. An organic light-emitting display panel, comprising:
a first electrode and a second electrode that are stacked; and
at least two light-emitting layers are provided between the first electrode and the second electrode, wherein a first auxiliary functional layer and a second auxiliary functional layer are provided between adjacent the at least two light-emitting layers; and, wherein
the first auxiliary functional layer is close to the first electrode, the second auxiliary functional layer is close to the second electrode;
the first auxiliary functional layer comprises an electron transport-type host material, and the second auxiliary functional layer comprises a hole transport-type host material; and
the first auxiliary functional layer comprises an N-type dopant material, and/or the second auxiliary functional layer comprises a P-type dopant material.

2. The organic light-emitting display panel according to claim 1, wherein
the N-type dopant material comprises at least one of an alkali metal, an alkaline earth metal and a rare-earth metal.

3. The organic light-emitting display panel according to claim 1, wherein
the N-type dopant material comprises ytterbium.

4. The organic light-emitting display panel according to claim 1, wherein
a mass percent of the N-type dopant material in the first auxiliary functional layer is greater than or equal to 5% and is less than or equal to 50%.

5. The organic light-emitting display panel according to claim 1, wherein
a thickness of the first auxiliary functional layer is greater than or equal to 10 nm and is less than or equal to 60 nm.

6. The organic light-emitting display panel according to claim 1, wherein the P-type dopant material comprises at least one of 2,3,6,7,10,11-hexacyano-1,4,5,8,9,12-hexaazatriphenylene, 2,3,5,6-tetrafluoro-7,7′,8,8′-tetracyanoquinodimethane or molybdenum oxide.

7. The organic light-emitting display panel according to claim 1, wherein
a mass percent of the P-type dopant material in the second auxiliary functional layer is greater than or equal to 1% and is less than or equal to 10%.

8. The organic light-emitting display panel according to claim 1, wherein
a thickness of the second auxiliary functional layer is greater than or equal to 20 nm and is less than or equal to 100 nm.

9. The organic light-emitting display panel according to claim 1, wherein
the light-emitting layer comprises at least one host material and at least one guest dopant.

10. The organic light-emitting display panel according to claim 9, wherein, the host material in the light-emitting layer comprises at least one of the following strcutures:

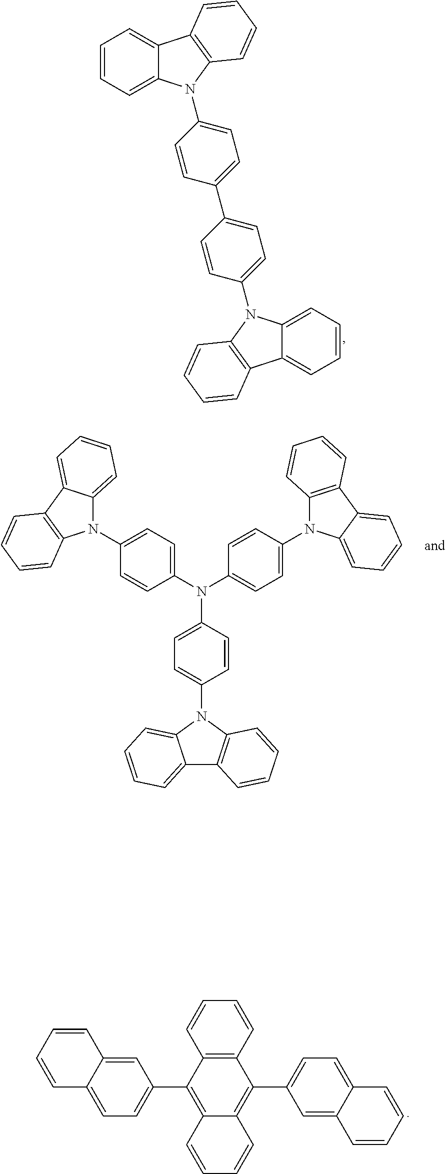

11. The organic light-emitting display panel according to claim 9, wherein
the guest dopant in the light-emitting layer is a phosphorescent material or a fluorescent material.

12. The organic light-emitting display panel according to claim 11, wherein
the guest dopant in the light-emitting layer is a phosphorescent material; and
the phosphorescent material comprises at least one of
tri(2-phenylpyridinato)iridium(III),
bis(4,6-difluorophenylpyridinato-N,C2)picolinatoiridium, or
bis(2-(T-benzothienyl)pyridinato-N,C3′)(acetylacetonate)iridium.

13. The organic light-emitting display panel according to claim 12, wherein
a thickness of the light-emitting layer is greater than or equal to 20 nm and is less than or equal to 40 nm.

14. The organic light-emitting display panel according to claim 11, wherein
the guest dopant in the light-emitting layer is a fluorescent material;
the fluorescent material comprises at least one of the following:

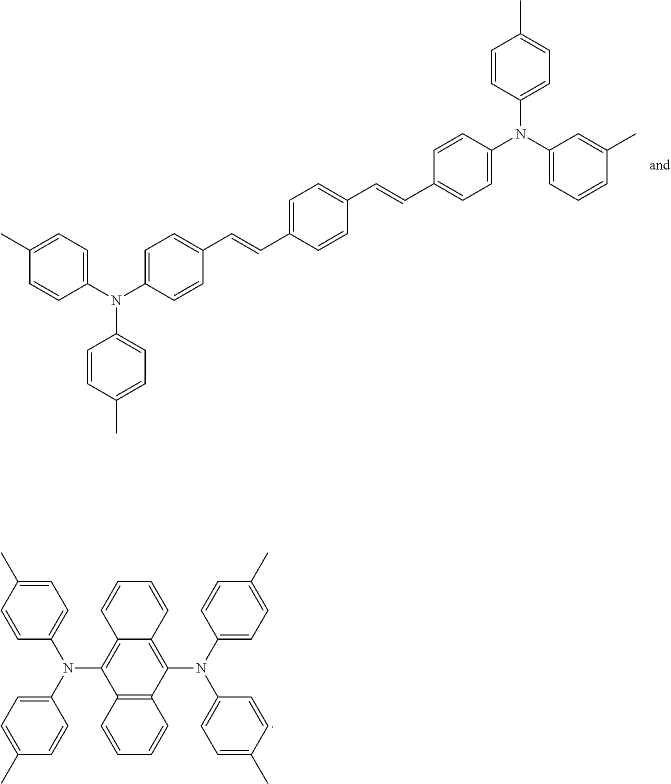

15. The organic light-emitting display panel according to claim 14, wherein
a thickness of the light-emitting layer is greater than or equal to 15 nm and is less than or equal to 40 nm.

16. The organic light-emitting display panel according to claim 1, wherein
the organic light-emitting display panel further comprises a third auxiliary functional layer and/or a fourth auxiliary functional layer;
the third auxiliary functional layer is located between the first electrode and the light-emitting layer closest to the first electrode, and the third auxiliary functional layer comprises at least one of a hole injection layer, a hole transport layer and an electron blocking layer; and
the fourth auxiliary functional layer is located between the second electrode and the light-emitting layer closest to the second electrode, and the fourth auxiliary functional layer comprises at least one of an electrode injection layer, an electron transport layer and a hole blocking layer.

17. An organic light-emitting display device, comprising an organic light-emitting display panel,
wherein the organic light-emitting display panel comprises:
a first electrode and a second electrode that are stacked; and
at least two light-emitting layers provided between the first electrode and the second electrode, wherein a first auxiliary functional layer and a second auxiliary functional layer are provided between adjacent the at least two light-emitting layers; and, wherein the first auxiliary functional layer is close to the first electrode, the second auxiliary functional layer is close to the second electrode;
the first auxiliary functional layer comprises an electron transport-type host material, and the second auxiliary functional layer comprises a hole transport-type host material; and
the first auxiliary functional layer comprises an N-type dopant material, and/or, the second auxiliary functional layer comprises a P-type dopant material.

18. The organic light-emitting display device according to claim 17, wherein the N-type dopant material comprises at least one of an alkali metal, an alkaline earth metal and a rare-earth metal.

19. The organic light-emitting display device according to claim 17, wherein the N-type dopant material comprises ytterbium.

20. The organic light-emitting display device according to claim 17, wherein a mass percent of the N-type dopant material in the first auxiliary functional layer is greater than or equal to 5% and is less than or equal to 50%.
